(19) United States
(12) Patent Application Publication
(10) Pub. No.: US 2026/0194719 A1
(43) Pub. Date: Jul. 9, 2026

(54) SEMICONDUCTOR STRUCTURES AND METHOD OF FABRICATING THE SAME

(71) Applicant: Taiwan Semiconductor Manufacturing Company, Ltd., Hsinchu (TW)

(72) Inventors: Feng-Wei Kuo, Hsinchu (TW); Chewn-Pu Jou, Hsinchu (TW); Stefan Rusu, Hsinchu (TW); Jyh Chwen Frank Lee, Hsinchu (TW)

(73) Assignee: Taiwan Semiconductor Manufacturing Company, Ltd., Hsinchu (TW)

(21) Appl. No.: 19/216,067

(22) Filed: May 22, 2025

Related U.S. Application Data
(60) Provisional application No. 63/741,717, filed on Jan. 3, 2025.

(51) Int. Cl. G02B 6/34; G02B 6/12; G02B 6/42; H01L 23/00; H01L 23/48; H01L 23/538; H01L 25/00; H01L 25/16

(52) U.S. Cl. CPC G02B 6/34; G02B 6/12; G02B 6/4212; H10W 20/20; H10W 90/00; G02B 2006/12107; G02B 2006/12147; H10W 70/611; H10W 70/65; H10W 90/792

(57) ABSTRACT

An optical structure includes a substrate, a first dielectric layer disposed over the substrate, a coupler layer disposed over the first dielectric layer, a grating coupler formed in a first portion of the coupler layer, and a semiconductor layer disposed between the first dielectric layer and the coupler layer. The coupler layer includes a first material having a first refractive index. The semiconductor layer includes a second material having a second refractive index greater than the first refractive index.

### CROSS-REFERENCE TO REALTED APPLICATIONS

This application claims priority to and the benefit of U.S. Provisional Application Number 63/741717, filed Jan. 3, 2025, the disclosure of which is incorporated herein by reference in its entirety for all purposes.

### BACKGROUND

Silicon photonic technologies are emerging as important roles for high-speed optical data communication. For instance, optical transceiver modules including high-speed phase modulators, grating couplers and waveguides are used in high-speed optical communication systems. The optical transceiver modules comply with various international standard specifications at communication speeds ranging up to more than 100 Gbps. The performance of the optical transceiver modules is determined by coupling efficiency of the grating couplers in the optical transceiver modules. Although structures of existing grating couplers used for optical transceiver modules have been generally adequate, they are not entirely satisfactory in all aspects.

### BRIEF DESCRIPTION OF FIGURES

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an example optical transceiver, in accordance with some embodiments of the present disclosure.

FIG. 2 is a schematic illustration of a cross-sectional view of an example optical package including at least a semiconductor device and an optical interposer, in accordance with some embodiments of the present disclosure.

FIG. 3 is a top view of an embodiment of a portion of the optical interposer of FIG. 2, in accordance with some embodiments of the present disclosure.

FIGS. 4, 5, 6, and 7 are each a cross-sectional view of an embodiment of the portion of the optical interposer including a grating coupler taken along line AA′ of FIG. 3, in accordance with some embodiments of the present disclosure.

FIGS. 8, 9, and 10 are each a cross-sectional view of a portion of the grating coupler of any of FIGS. 3-7, in accordance with some embodiments of the present disclosure.

FIGS. 11, 12, and 13 are each a cross-sectional view of the grating coupler of any of FIGS. 3-7, in accordance with some embodiments of the present disclosure.

FIGS. 14A and 14B are each a flowchart of an example method of fabricating an example optical package of FIG. 2, in accordance with some embodiments of the present disclosure.

FIGS. 15, 16, 17, 18, 19, 20, 21, 22, 23, 24, 25, 26, and 27 are cross-sectional views of the optical package of FIG. 2, in portion or entirety, during intermediate stages of the methods of FIGS. 14A and 14B, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

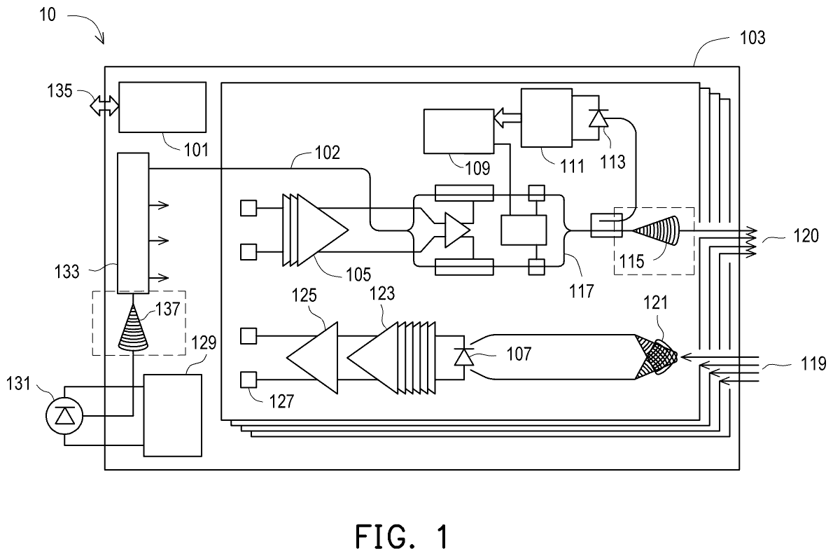

FIG. 1 illustrates a block diagram of an example optical transceiver 10. The optical transceiver 10 may include optical modulators 117, monitor photodiode 113, and grating couplers 115 and 121. The optical transceiver 10 may also include electrical devices and circuits including amplifiers 105 and 123, an analog to digital converter circuit 111, a digital control circuit 101, a photodiode(s) 107 and control section 109. The amplifiers 105 and 123 may include transimpedance and limiting amplifiers (TIA/LAs), for example. In some embodiments, the optical transceiver 10 further includes a photonic die 103 with a laser assembly. In some embodiments, the laser assembly includes one or more laser 131, lenses, rotators for directing one or more continuous-wave (CW) optical signals, and one or more laser driver 129.

In further embodiments, the optical transceiver 10 includes an input grating coupler 137 that is configured to receive an optical signal from the laser 131 and an optical splitter 133 that is configured to split the optical signal into four roughly equal power optical signals. In various embodiments, the split power signals are transmitted from the optical splitter 133 to the optical modulators 117 through optical waveguides. In some embodiments, the optical splitter 133 is coupled to the input grating coupler 137 and at least four output waveguides 102. In some embodiments, the optical splitter 133 includes a low-loss Y-junction power splitter. In some embodiments, the input grating coupler 137 includes a single-polarization grating coupler (SPGC). In some embodiments, the SPGC is a one-dimensional (1D) grating coupler.

In some embodiments, the optical modulators 117 include Mach-Zehnder or ring modulators, for example, and enable the modulation of the CW laser input signal. The optical modulators 117 may also include high-speed and low-speed phase modulation sections and are controlled by the control sections 109. In some embodiments, at least one of outputs of each of the optical modulators 117 is optically coupled to an optical output 120 such as an optical fiber via the grating coupler 115. In some embodiments, the grating coupler 115 includes an SPGC. The other outputs of the optical modulators 117 may be optically coupled to the monitor photodiode 113 that is configured to provide a feedback path from the output of the optical modulators 117 to the control section 109.

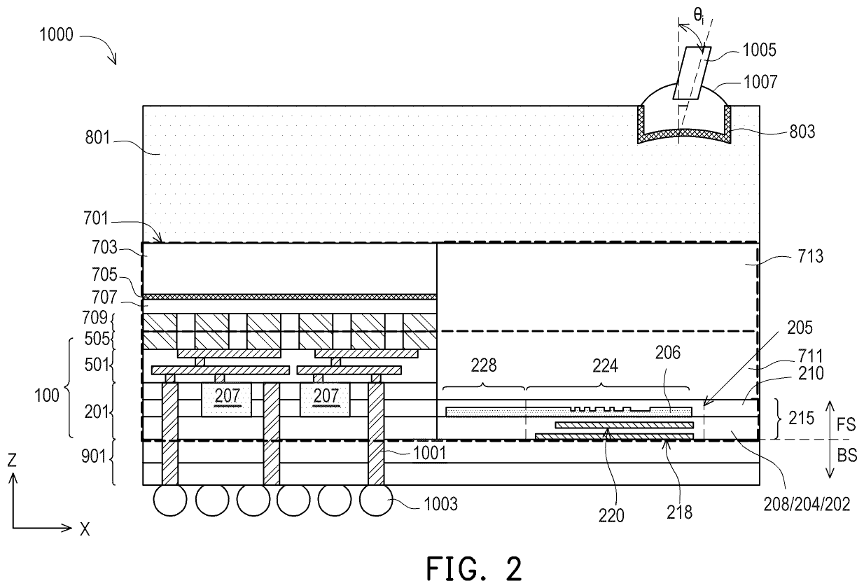

Furthermore, the optical transceiver 10 may also utilize a grating coupler (e.g., grating coupler 224 in FIG. 2) for receiving optical signals from an optical fiber (e.g., optical fiber 1005 in FIG. 2) or an array of optical fibers. In the present embodiments, the grating coupler 121 includes a polarization splitting grating coupler (PSGC) that utilizes two waveguides (or output waveguides) to transmit received optical signals to the photodiode(s) 107.

In some embodiments, the optical transceiver 10 employs the photodiode(s) 107, which may be implemented with epitaxial germanium (Ge)/silicon germanium (SiGe) films deposited directly on silicon (Si). In some embodiments, the photodiode(s) 107 may include high-speed heterojunction phototransistors, for example, and may include Ge in the collector and base regions for absorption in the 1200 nm to 1600 nm wavelength range (e.g., in the range of 1310 nm to 1550 nm), and may be integrated on a complementary metal-oxide-semiconductor (CMOS) silicon-on-insulator (SOI) wafer. The photodiode(s) 107 may be configured to convert optical signals received from the grating coupler 121 into electrical signals that are communicated to a receiver (Rx) 123 which may be configured to combine data streams, and demultiplex the received optical signals. Furthermore, the received optical signals may be amplified by a transimpedance amplifier 125, for example, and subsequently communicated to a small form-factor pluggable (SFP) interface circuitry 127. In some embodiments, the optical transceiver 10 also includes a digital control circuit 101 coupled to a serial interface 135 and configured to communicate received optical data through the serial interface 135.

As shown in FIG. 1, the grating couplers 115 and 137 of the optical transceiver 10 enable coupling of light into and out of the integrated circuit comprising the optical transceiver 10. In some embodiments, the geometry parameters of the grating couplers 115 and 137 may be parametrized during the routing and layout of the photonically-enabled integrated circuit and optimized based on the performance index.

FIG. 2 illustrates a cross-sectional view of an example semiconductor structure implemented as an optical package 1000, according to some embodiments of the present disclosure. In some embodiments, the optical package 1000 is configured as a compact universal photonic engine (COUPE) and thus may be alternatively referred to as the COUPE 1000.

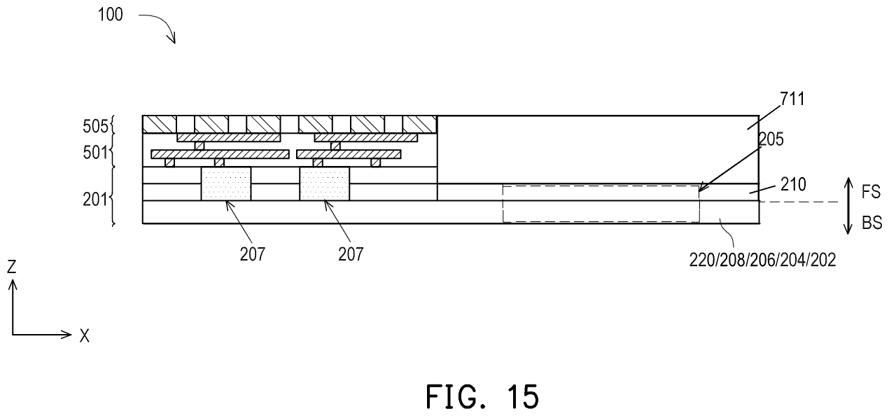

In some embodiments, the optical package 1000, which may also be generally referred to as a semiconductor structure 1000, includes a photonic die 100 (alternatively referred to as a semiconductor structure 100 or an optical structure 100) having a plurality of components disposed (or formed) over a semiconductor substrate 202 (alternatively referred to as a first semiconductor substrate 202). In some embodiments, the photonic die 100 includes a photonic integrated circuit (PIC) and may be alternatively referred to as a PIC 100. A first portion (e.g., a first portion 100A as depicted in FIG. 15) of the photonic die 100 includes an (optically) active layer 201 having one or more optical components 207 disposed therein (e.g., in a dielectric layer not depicted separately). The optical components 207 are coupled to metallization layers 501 disposed over the semiconductor substrate 202.

Additionally, the photonic die 100 includes a bonding layer 505 (alternatively referred to as a first bonding layer 505) disposed over the metallization layers 501 and configured to couple the metallization layers 501, and thus the active components 207, to a semiconductor device 701 as described below. In some embodiments, the bonding layer 505 includes a plurality of bonding pads (not depicted separately) disposed in a dielectric layer (not depicted separately).

A second portion (e.g., a second portion 100B as depicted in FIG. 15) of the photonic die 100 includes a dielectric layer 711 (alternatively referred to as a gap-fill layer 711) disposed over the semiconductor substrate 202 and adjacent to the first portion 100A, where the dielectric layer 711 abuts a sidewall of the active layer 201, a sidewall of the metallization layers 501, and a sidewall of the bonding layer 505. The dielectric layer 711, similar to the bonding layer 505, is configured to couple to a portion of the overlaying semiconductor device 701. In the present embodiments, the dielectric layer 711 is disposed over optical components 215 of the photonic die 100, which are described in detail below. The dielectric layer 711 may include any suitable material, such as silicon oxide (SiO₂).

The photonic die 100 also includes a dielectric layer 210 (alternatively referred to as a third dielectric layer 210 as described in detail below) disposed over or above the semiconductor substrate 202 along a vertical direction (e.g., the Z axis). The photonic die 100 further includes a dielectric layer 204 (alternatively referred to as a first dielectric layer 204 as described in detail below; not depicted separately in FIG. 2) disposed between the dielectric layer 210 and a second portion of the semiconductor substrate 202 adjacent to the first portion. Still further, in some embodiments, the photonic die 100 includes a dielectric layer 208 (alternatively referred to as a second dielectric layer 208 as described in detail below; not depicted separately in FIG. 2) disposed between the dielectric layer 204 and the dielectric layer 210. In some embodiments, the dielectric layer 208 is omitted from the photonic die 100.

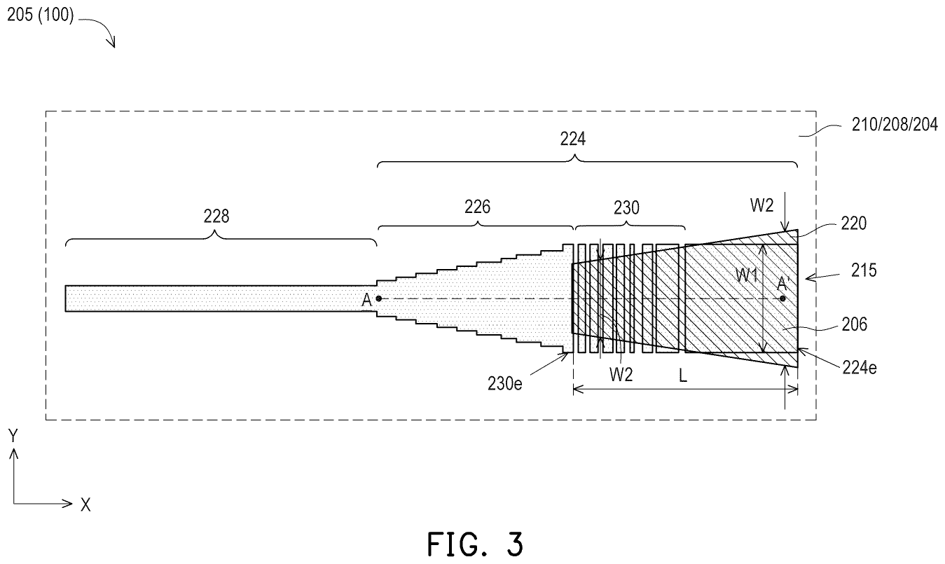

Still referring to FIG. 2, the photonic die 100 further includes a coupler layer 206 disposed between a frontside FS of the semiconductor substrate 202 and the dielectric layer 210. As described in detail below, the coupler layer 206 includes the grating coupler 224 and a waveguide 228 coupled to the grating coupler 224 through a tapered structure 226 (see FIG. 3; not depicted separately in FIG. 2) along a first lateral direction (e.g., the X axis). The grating coupler 224 is configured to receive and modulate optical input from the optical fiber 1005 provided and guided through a coupling lens 803 disposed on a support substrate 801 as depicted in FIG. 2. In the present embodiments, the coupler layer 206 includes a material having a refractive index of less than that of silicon (Si), as described in detail below. In some embodiments, the coupler layer 206 includes silicon nitride, lithium niobate, the like, or combinations thereof.

In some embodiments, the photonic die 100 further includes a semiconductor layer 220 disposed between the coupler layer 206 and the dielectric layer 204. In some embodiments, the semiconductor layer 220 includes silicon in elemental form. In some embodiments, the semiconductor layer 220 essentially consists of silicon and may alternatively be referred to as the silicon layer 220. In some embodiments, the semiconductor layer 220 only partially, i.e., not fully, covers a top surface of the dielectric layer 204. In some embodiments, the semiconductor layer 220 is omitted from the photonic die 100.

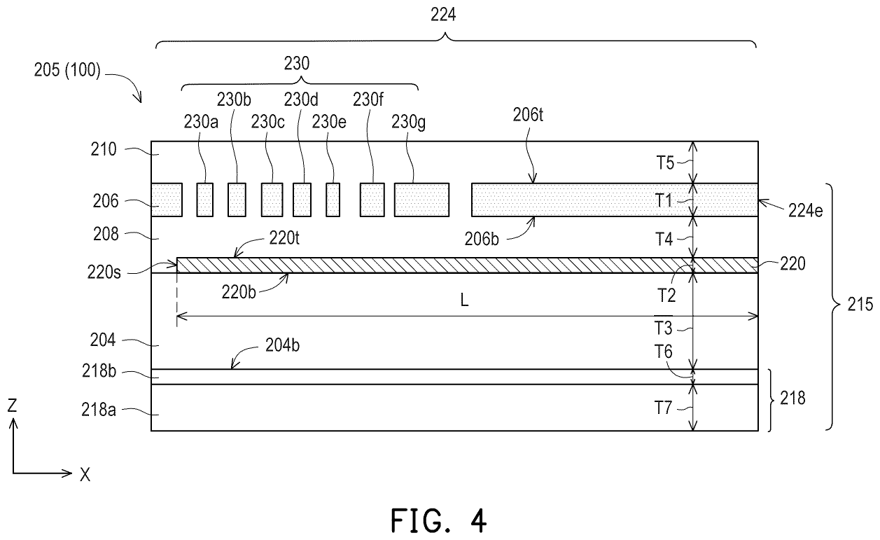

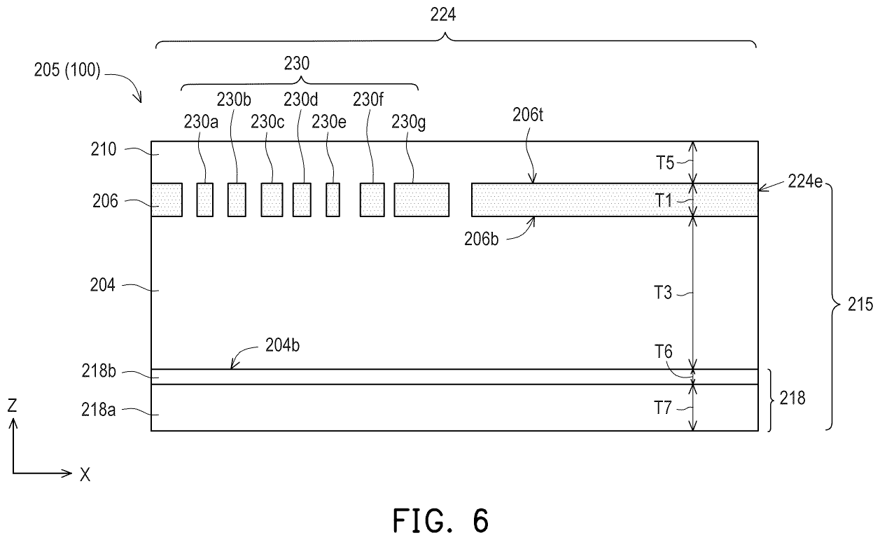

In some embodiments, the photonic die 100 further includes a metal layer 218 (alternatively referred to as the metal reflector 218, the reflective layer 218, or the metal mirror 218) disposed on and extending over a bottom surface (e.g., bottom surface 204b) of the dielectric layer 204 (see FIGS. 4 and 6). In some embodiments, the metal layer 218 is embedded in the semiconductor substrate 202 along the backside BS (see FIG. 2). The metal layer 218 is configured to reflect or recycle any optical input tunneled through the coupler layer 206 back to the grating coupler 224 to improve the coupling efficiency of the grating coupler 224.

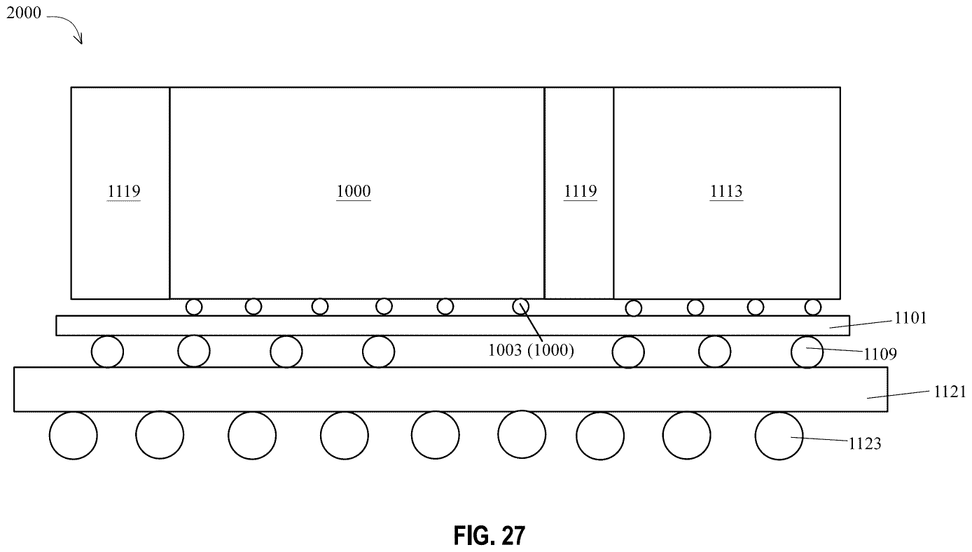

In some embodiments, the optical package 1000 includes one or more dielectric layers 901 disposed along the backside BS of the semiconductor substrate 202. Though not depicted separately, the optical package 1000 may include conductive features (e.g., metallization layers, redistribution layers, etc.) disposed in the dielectric layers 901. The dielectric layers 901 are configured to facilitate the bonding and electrical connection between the optical package 1000 (e.g., the photonic die 100) and additional packaging components (see FIG. 27). For example, the optical package 1000 may include a plurality of external connectors 1003 (alternatively referred to as first external connectors 1003) coupled to the dielectric layers 901. Additionally, the optical package 1000 includes a plurality of through-device-vias (TDVs; alternatively referred to as through-dielectric-vias) 1001 each extending from, thereby coupling, one of the external connectors 1003 to a portion of the photonic die 100, such as the metallization layers 501, which is further coupled to the semiconductor device 701 through the bonding layers 505 and 709. In some embodiments, the TDVs 1001 extend through the dielectric layers 901 and the active layer 201 to provide a quick passage of power, data, and ground connection through the photonic die 100.

The optical package 1000 further includes the semiconductor device 701 bonded to the bonding layer 505 of the photonic die 100. In some embodiments, the semiconductor device 701 includes an electronic integrated circuit (EIC) and may be alternatively referred to as an EIC 701, an electronic device 701, or an electronic structure 701. The semiconductor device 701 includes a semiconductor substrate 703 (alternatively referred to as a second semiconductor substrate 703) and a device layer 705 overlaying the semiconductor substrate 703. The semiconductor device 701 includes interconnect structures 707, which overlays and is coupled to the device layer 705, and a bonding layer 709 (alternatively referred to as a second bonding layer 709) coupled to the interconnect structures 707. Similar to the bonding layer 505, the bonding layer 709 may include a plurality of bonding pads (not depicted separately) disposed in a dielectric layer (not depicted separately). In this regard, the semiconductor device 701 is bonded to the photonic die 100 by coupling the bonding layer 709 to the bonding layer 505.

In some embodiments, the device layer 705 includes one or more devices such as transistors, capacitors, resistors, the like, or combinations thereof. In some examples, the semiconductor device 701 may be configured to work with the photonic die 100 for a desired functionality. For example, the semiconductor device 701 may be configured as a high bandwidth memory (HBM) module, an xPU, a logic die, a 3DIC die, a CPU, a GPU, a SoC die, a MEMS die, the like, or combinations thereof. Any suitable device with any suitable functionality, may be used, and all such devices are fully intended to be included within the scope of the embodiments.

The semiconductor device 701 further includes a dielectric layer 713 (alternatively referred to as a gap-fill layer 713) adjacent to the semiconductor substrate 703, the device layer 705, the interconnect structures 707, and the bonding layer 709., In the present embodiments, the dielectric layer 713 is bonded to the dielectric layer 711 of the photonic die 100 by any suitable bonding process (e.g., a dielectric-to-dielectric bonding process). In this regard, the dielectric layers 711 and 713 are disposed in a portion of the optical package 1000 corresponding to a location of the coupler layer 206. In some embodiments, the dielectric layer 713 includes the same composition as the dielectric layer 711. The combination of the dielectric layers 711 and 713 may provide additional structural support for the bonded dies in the optical package 1000.

Still referring to FIG. 2, the optical package 1000 further includes a support substrate 801 bonded to the semiconductor device 701 and the dielectric layer 713. In some embodiments, the support substrate 801 includes a support material that is transparent to the wavelength of an incident light (i.e., optical input) received by the grating coupler 224 of the photonic die 100. In some embodiments, the support substrate 801 includes silicon. In some embodiments, the support substrate 801 includes the coupling lens 803 configured to facilitate and guide emission of the incident light from the optical fiber 1005 towards the grating coupler 224 disposed in the coupler layer 206 of the photonic die 100.

In some embodiments, the optical fiber 1005 is configured to provide optical input to the grating coupler 224 in the photonic die 100 through the dielectric layer 713. In some embodiments, the incident light emitted from a fiber core (not depicted separately) of the optical fiber 1005 is applied at an incident angle θᵢ, which is defined as an angle between an axis along which the fiber core extends and a normal (not depicted separately) of the photonic die 100 (i.e., a normal of a top surface of the semiconductor substrate 203 or the coupler layer 206). In some examples, the incident angle θi may be about 0° to about 15°, though the present disclosure is not limited to such a range. In some embodiments, the incident angle θᵢ is configured to lower the reflection of the incident light off the grating coupler 224, thereby increasing the coupling efficiency of the grating coupler 224. In some embodiments, the optical fiber 1005 is implemented as a single-mode fiber (SMF) and is attached to the support substrate 801 by an optical glue 1007, for example.

In some examples, the optical package 1000 may be implemented as a portion of the optical transceiver 10 depicted within each dashed enclosure in FIG. 1. For example, a grating coupler (e.g., the grating coupler 224) of the photonic die 100 of the optical package 1000 may correspond to the grating coupler 115 or 137 and a waveguide (e.g., the waveguide 228) coupled to the grating coupler in the photonic die 100 may correspond to the waveguide 102. A tapered structure (e.g., the tapered structure 226) extends between a portion of the grating coupler that receive and modulate optical input (e.g., the grating lines 230 of the photonic die 100) and the waveguide.

FIG. 3 illustrates a top view of a portion 205 of the photonic die 100 of FIG. 2, according to some embodiments of the present disclosure. The photonic die 100, as illustrated in the portion 205, includes optical components, collectively referred to as the optical components 215, disposed in a plurality of dielectric layers, including dielectric layers 204, 208, and 210 (not depicted separately in FIG. 3 but are depicted in detail in the subsequent figures) stacked along the vertical direction. For purposes of discussion, the portion 205 corresponds to a portion of the photonic die 100 within the dashed enclosure below the dielectric layer 711 as depicted in FIG. 2.

As shown in FIG. 3, the optical components 215 include at least the grating coupler 224 disposed in the coupler layer 206 The grating coupler 224 includes the tapered structure 226 (also referred to as the tapered region 226) that is disposed adjacent to the waveguide 228. The grating coupler 224 (i.e., the coupler layer 206) includes a plurality of grating lines 230 configured to receive and modulate optical input from an optical fiber (e.g., optical fiber 1005 (or an array thereof); see FIG. 2), and the modulated optical input is subsequently transmitted to the waveguide 228 through the tapered structure 226. In the depicted embodiments, the grating coupler 224 and the waveguide 228 are arranged adjacent to one another along the first lateral direction. In some embodiments, the tapered structure 226 is disposed immediately adjacent to the waveguide 228 along the first lateral direction. The grating coupler 224 is disposed over (or in) a first portion of the coupler layer 206, while the waveguide 228 is disposed over (or in) a second portion of the coupler layer 206 adjacent to the first portion. In this regard, the coupler layer 206 is alternatively referred to as a device layer 206 (or photonic device layer 206).

In the present embodiments, the coupler layer 206 includes a material having a refractive index less than that of silicon (Si) in elemental form. In some embodiments, the coupler layer 206 is substantially free of silicon in elemental form. In some embodiments, the coupler layer 206 includes a dielectric material with a refractive index of less than that of silicon, which generally has a refractive index of about 3.5. For example, the coupler layer 206 may include silicon nitride (SiₓN_{y}, where x may be 3 and y may be 4), lithium niobate (LiNbO_{z}, where z may be 3), the like, or a combination thereof. In some embodiments, silicon nitride generally has a refractive index of about 1.7 to about 2.2, and lithium niobate generally has a refractive index of about 2.3. In this regard, the coupler layer 206 is alternatively referred to as a dielectric coupler layer 206. Other suitable materials exhibiting refractive indices less than that of silicon may also be implemented in the coupler layer 206.

In some embodiments, by employing a material with a relatively lower refractive index (as compared to silicon, which is used in existing technologies), the range of the bandwidths of the light received and subsequently modulated by the grating coupler 224 may be widened. Furthermore, when implemented with additional optical components 215 (e.g., the semiconductor layer 220 and/or the metal layer 218 described below) on a backside of the coupler layer 206, the efficiency and overall bandwidth of the grating coupler 224 in the photonic die 100 may also be enhanced.

Still referring to FIG. 3, the optical components 215 further include the semiconductor layer 220 extending along the first lateral direction at a position directly below the coupler layer 206 along the vertical direction (see FIG. 4). Though not depicted in the top view of FIG. 3, the photonic die 100 may further include a dielectric layer (e.g., the (second) dielectric layer 208 depicted in FIG. 4) disposed between the coupler layer 206 and the semiconductor layer 220. In addition, another dielectric layer (e.g., the (third) dielectric layer 210 depicted in FIG. 4) may be disposed over (i.e., overlaying) the coupler layer 206. These dielectric layers are omitted from the depiction in FIG. 3 for purposes of clarity only.

In the present embodiments, the semiconductor layer 220 has a length L extending from an edge 224e of the grating coupler 224 to at least an edge 231e of the tapered structure 226. In some embodiments, the length L extends from the edge 224e towards the tapered region 226 such that the semiconductor layer 220 overlaps at least the grating lines 230 along the first lateral direction when viewed in a top view (e.g., in the X-Y plane) of FIG. 3. In some embodiments, a portion of the grating coupler 224 overlaying the semiconductor layer 220 has a width W1 that remains substantially constant between the edge 224e and the edge 231e along the first lateral direction. In contrast, the semiconductor layer 220 has a width W2 that gradually decreases from the edge 224e towards the edge 231e. For example, at the edge 224e, the width W2 is greater than the width W1, and at the edge 231e, the width W2 is less than the width W1. In some embodiments, as shown in the top view in FIG. 3, the semiconductor layer 220 is configured to have a trapezoidal shape with a tip (i.e., the narrower end) of the trapezoidal shape proximate to the tapered region 226 and a base (i.e., the wider end) of the trapezoidal shape distal to the tapered region 226. Accordingly, in some examples, the semiconductor layer 220 is configured, and thus alternatively referred to, as the silicon tip 220. The gradually decreasing width W2 of the semiconductor layer 220 towards the tapered structure 226 allows the optical input reflected by the semiconductor layer 220 to be captured towards the tapered structure 226, thereby enhancing the coupling efficiency of the grating coupler 224.

In some embodiments, the semiconductor layer 220 is configured such that the width W2 is less than the width W1 across the region of the coupler layer 206 in which the grating lines 230 are disposed. As such, the semiconductor layer 220 fully overlaps with the grating lines 230, thereby ensuring that a substantial amount of the auxiliary optical input (e.g., auxiliary light) reflected from the semiconductor layer 220 can be fully captured, recycled, and directed to the grating coupler 224. In the present embodiments, providing the semiconductor layer 220 directly below and overlapping the grating coupler 224, particularly below the region of grating lines 230, allows auxiliary optical input to be directed into the grating lines 230 upon reflection by the semiconductor layer 220. This feature, alone or in combination with additional features such as silicon nitride material in the coupler layer 206 and/or the metal layer 218, enhances the efficiency of the grating coupler 224 by capturing the auxiliary optical input that would otherwise be lost in the absence of the underlying semiconductor layer 220. I

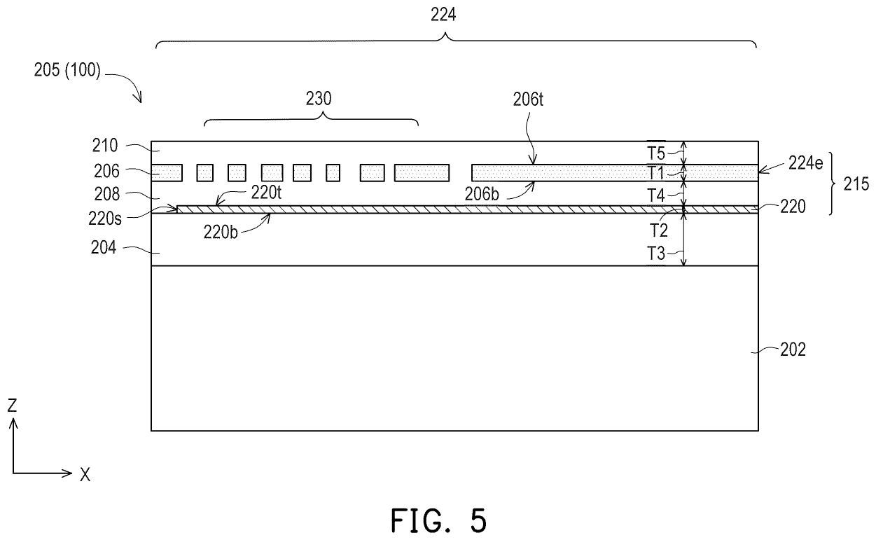

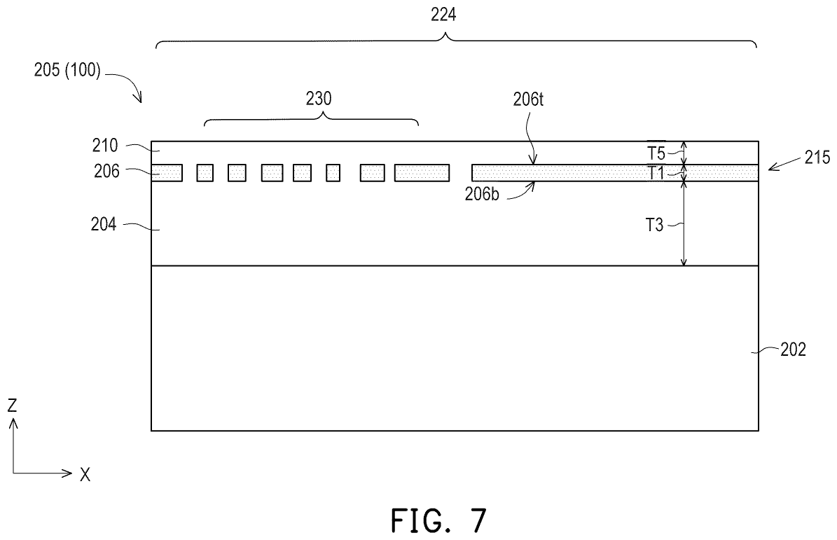

FIGS. 4, 5, 6, and 7 illustrate various embodiments of the portion 205 of the photonic die 100 in which one or more of the optical components 215 configured to enhance the coupling efficiency and bandwidths, i.e., the grating coupler 224 comprising a material different form silicon, the semiconductor layer 220, and the metal layer 218, are included. Specifically, FIGS. 4 and 5 are cross-sectional views of the portion 205 taken along line AA′ of FIG. 3, according to some embodiments in which the photonic die 100 includes the semiconductor layer 220 described above. In some embodiments, with the exception of the grating coupler 224, one or more of the optical components 215 is omitted from the photonic die 100. For example, as depicted in the cross-sectional views of the portion 205 in FIGS. 6 and 7, the semiconductor layer 220 is omitted from the photonic die 100.

In some embodiments, referring to FIGS. 4-7 collectively, the photonic die 100, as shown in the portion 205, includes the dielectric layer 204 over which the coupler layer 206 is disposed. In the present embodiments, the dielectric layer 204 overlays the semiconductor substrate 202 as shown in FIG. 2. In some embodiments, referring to FIGS. 4 and 5, the dielectric layer 204 directly contacts and extends along a bottom surface 220b of the semiconductor layer 220 such that the semiconductor layer 220 is disposed or sandwiched between the coupler layer 206 and the dielectric layer 204 along the vertical direction. In some embodiments, referring to FIGS. 6 and 7, the dielectric layer 204 directly contacts and extends along a bottom surface 206b of the coupler layer 206 in the absence of the semiconductor layer 220. In some embodiments, still referring to FIGS. 4-7 collectively, the photonic die 100 further includes the dielectric layer 210 disposed over the coupler layer 206. In some embodiments, the dielectric layer 210 directly contacts and extends over a top surface 206t of the coupler layer 206.

In some embodiments, referring to FIGS. 4 and 5, the photonic die 100 further includes the dielectric layer 208 disposed or sandwiched between the semiconductor layer 220 and the coupler layer 206 along the vertical direction. In some embodiments, the dielectric layer 208 directly contacts and extends along both a top surface 220t and a sidewall surface 220s of the semiconductor layer 220 such that the semiconductor layer 220 is encapsulated in or embedded between the dielectric layers 204 and 208. In some embodiments, the dielectric layers 204 and 208 have the same composition such that the two layers coalesce with one another and extend continuously around the sidewall surface 220s of the semiconductor layer 220. For embodiments in which the semiconductor layer 220 is omitted from the photonic die 100, such as depicted in FIGS. 6 and 7, the dielectric layer 208 is also omitted and the dielectric layer 204 extends from the semiconductor substrate 202 or the metal layer 218 to the bottom surface 206b of the coupler layer 206.

The dielectric layers 204, 208, and 210 may each include any suitable dielectric material, such as silicon oxide. In the present embodiments, the dielectric layers 204, 208, and 210 each have a composition different from that of the coupler layer 206. For example, the dielectric layers 204, 208, and 210 may each be free, or substantially free, of any silicon nitride and lithium niobate. In some embodiments, the dielectric layers 204, 208, and 210 have the same, or substantially the same, composition. For example, the dielectric layers 204, 208, and 210 may each include silicon oxide. In some examples, the dielectric layers 204, 208, and 210 may each essentially consist of silicon oxide.

Referring to FIGS. 4 and 6 collectively, the photonic die 100 further includes the metal layer 218 extending along the bottom surface 204b of the dielectric layer 204 that is opposite to the coupler layer 206. In some embodiments, the metal layer 218 is disposed between portions of the semiconductor substrate 202 along the first lateral direction (see FIG. 2) such that it is embedded between the dielectric layer 204 and the semiconductor substrate 202. In the present embodiments, the metal layer 218, the semiconductor layer 220, and at least the grating lines 230 of the grating coupler 224 are aligned along the vertical direction.

In the present embodiments, the metal layer 218 is configured to reflect or recycle any optical input (or optical signals) tunneled through the coupler layer 206 (and the underlying dielectric layer 204) back to the grating coupler 224, thereby improving the coupling efficiency of the grating coupler 224. For at least this reason, the metal layer 218 includes an optically reflective material. For example, the metal layer 218 may include copper (Cu), aluminum (Al), titanium (Ti), tantalum (Ta), titanium nitride (TiN), tantalum nitride (TaN), ruthenium (Ru), manganese (Mn), the like, or combinations thereof.

In some embodiments, the metal layer 218 includes a single metal material/sublayer. In some embodiments, the metal layer 218 includes multiple metal materials/sublayers, such as a sublayer 218b over a sublayer 218a as depicted in FIGS. 4 and 6. In this regard, the sublayer 218a and 218b may include different metals described above. For example, the sublayer 218a may include copper and the sublayer 218b may include titanium. In some embodiments, the metal layer 218, or one or more of its sublayers, includes a seed layer configured to facilitate the deposition process.

In some embodiments, referring to FIGS. 5 and 7 collectively, the metal layer 218 is omitted from the photonic die 100. In this regard, rather than relying on the metal layer 218 for reflecting or recycling the optical input, the semiconductor substrate 202 may be utilized for the same application. Additionally, in some embodiments, referring to FIG. 5, the semiconductor layer 220 is additionally employed to reflect and recycle the auxiliary optical input and subsequently direct it to the grating coupler 224 as described in detail above.

Referring to FIGS. 4-7 collectively, the coupler layer 206 may have a thickness T1, the semiconductor layer 220 may have a thickness T2, the dielectric layer 204 may have a thickness T3, the dielectric layer 208 may have a thickness T4, and the dielectric layer 210 may have a thickness T5, each thickness measured along the vertical direction. In some embodiments, the thickness T1 is less than the thickness T3 and the thickness T2 is less than the thickness T1. In some embodiments, the thickness T5 is substantially similar to or the same as the thickness T4. For embodiments in which the semiconductor layer 220 is omitted from the photonic die 100, referring to FIGS. 6 and 7, the dielectric layer 208 is also omitted and the thickness T4 is thus zero.

In some examples, the thickness T1 may be about 100 nm to about 1 μm, such as at least about 400 nm. In some examples, the thickness T2 may be about 10 nm to about 500 nm, such as at least about 130 nm. In some examples, the thickness T3 may be a non-zero value that is less than about 3 μm, such as at least about 2 μm. In some examples, the thickness T4 may be about 0 nm to about 1 μm. In some examples, the thickness T5 may be about 10 nm to about 1 μm, such as at least about 200 nm.

In some embodiments, referring to FIGS. 3-7 collectively, the grating coupler 224 is a one-dimensional (1D) grating coupler, such as a single-polarization grating coupler. The grating coupler 224 includes a set of grating lines 230a, 230b, 230c, 230d, 230e, 230f, and 230g (collectively referred to as the grating lines 230 hereafter). The grating lines 230 may alternatively be referred to as scattering elements 230. Though not depicted herein, the grating lines 230 are each configured as a segment that curves around the waveguide 228. In some embodiments, the curved grating lines 230 are concentrically arranged in a pattern and spaced apart from one another along the first lateral direction. As will be described in detail below, a profile of each grating line 230, a width of each grating line 230 along the first lateral direction, a spacing between two adjacent grating lines 230, and a depth of a recess between two adjacent grating lines 230 may be adjusted to achieve a desired pattern in the grating coupler 224. It is noted that, although a set of seven grating lines 230 are depicted in FIGS. 3-7, embodiments of the photonic die 100 described in the present disclosure are not limited as such and may include, for example, more or less grating lines 230 in the grating coupler 224.

In the present embodiments, the grating lines 230 (and the corresponding recesses 250 described below) may be defined by shapes and dimensions that vary within the grating coupler 224 along the first lateral direction. In some instances, depending on design factors such as the peak loss and bandwidth (e.g., narrow bandwidth or wide bandwidth) of the grating coupler 224, the shapes and the dimensions of the grating lines 230, as well as the thicknesses of the various material layers disposed in the vicinity of the grating coupler 224, may be adjusted accordingly.

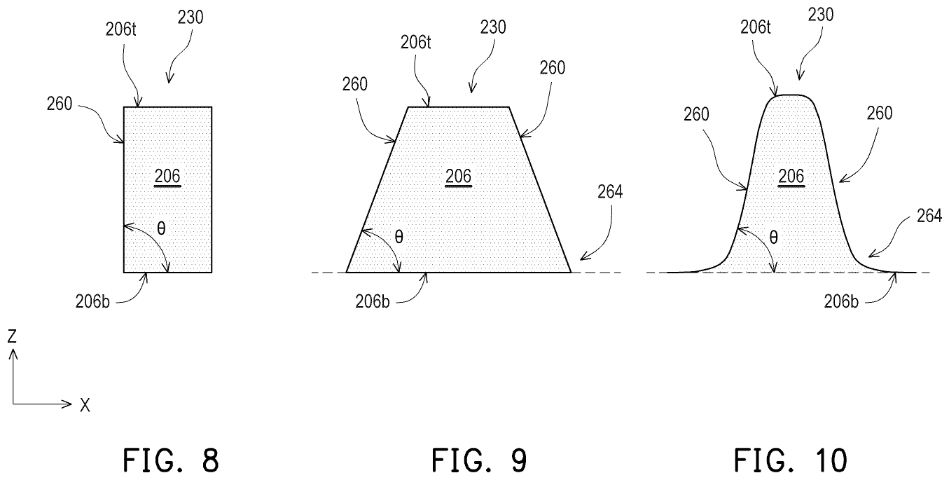

In some embodiments, the grating lines 230 may be defined by various profiles in cross-sectional views (e.g., in the X-Z plane). Referring to FIGS. 8, 9, and 10, which illustrate example embodiments of a cross-sectional view of a single grating line 230 (e.g., any of the grating lines 230a-230g depicted in FIG. 4), each sidewall 260 of the grating line 230 extends between the top surface 206t and the bottom surface 206 b of the coupler layer 206. Furthermore, each sidewall 260 forms a non-zero angle θ with the bottom surface 206b. In some embodiments, referring to FIG. 8, the sidewall 260 is substantially perpendicular to the bottom surface 206b such that the angle θ is about 90°. In other words, the profile of the grating line 230 has a substantially rectangular shape.

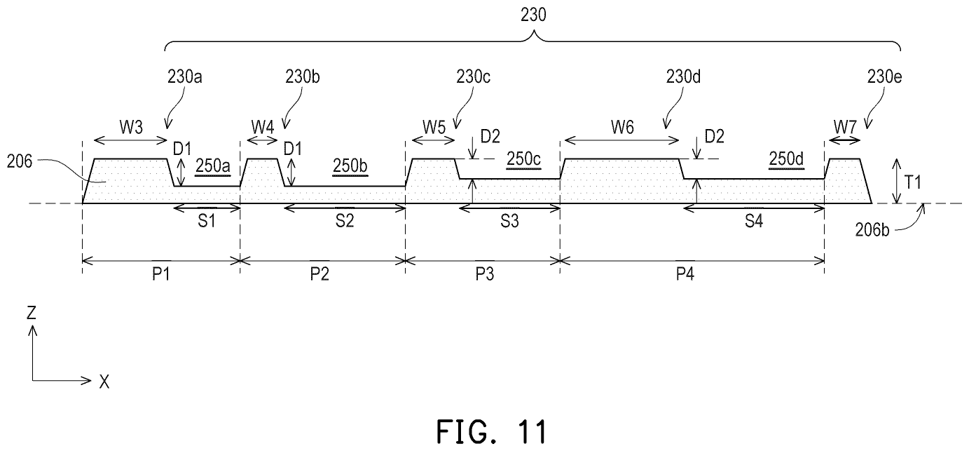

In some embodiments, referring to FIGS. 9 and 10, top portions of the opposing sidewalls 260 are slanted towards one another such that the angle θ is an acute angle (i.e., less than about 90°). In some examples, the angle θ may be about 60° to about 90°, such as at least about 85° and less than about 90°. In some embodiments, referring to FIG. 9, a bottom portion 264 of the sidewall 260 has an angled (or sharp) profile. In this regard, the profile of the grating line 230 has a substantially trapezoidal shape, as shown in embodiments of FIGS. 11, 12, and 13. Alternatively, referring to FIG. 10, the bottom portion 264 has a rounded (or smooth) profile. In this regard, the profile of the grating line 230 has an approximately bell-like shape. In some examples, referring to FIGS. 4-7, each grating line 230 has a substantially rectangular shape.

In some embodiments, dimensions of the grating lines 230 within the grating coupler 224 also vary along the first lateral direction. For example, FIGS. 11-13 illustrate different dimensions of the grating lines 230a-230e in cross-sectional views (e.g., in the X-Z plane), where the widths of the grating lines 230a-230e along the first lateral direction are defined as widths W3, W4, W5, W6, and W7, respectively. In addition, the grating lines 230a-230e are defined (or separated) by recesses 250a, 250b, 250c, and 250d (collectively referred to as recesses 250 hereafter) in the coupler layer 206. For example, the grating lines 230a and 230b are separated by the recess 250a; the grating lines 230b and 230c are separated by the recess 250b; the grating lines 230c and 230d are separated by the recess 250c; and the grating lines 230d and 230e are separated by the recess 250d. Accordingly, widths of the recess 250a-250d, expressed as S1, S2, S3, and S4, respectively, thus each define a spacing between two adjacent grating lines 230.

In some embodiments, referring to FIG. 11, the widths of the grating lines 230a-230e are different and randomized (i.e., following no pattern) such that no two widths are equal, e.g., W3≠W4≠W5≠W6≠W7. Furthermore, the spacings between the grating lines 230 are also different and randomized (i.e., following no pattern) such that no two spacings are equal, e.g., S1≠S2≠S3≠S4.

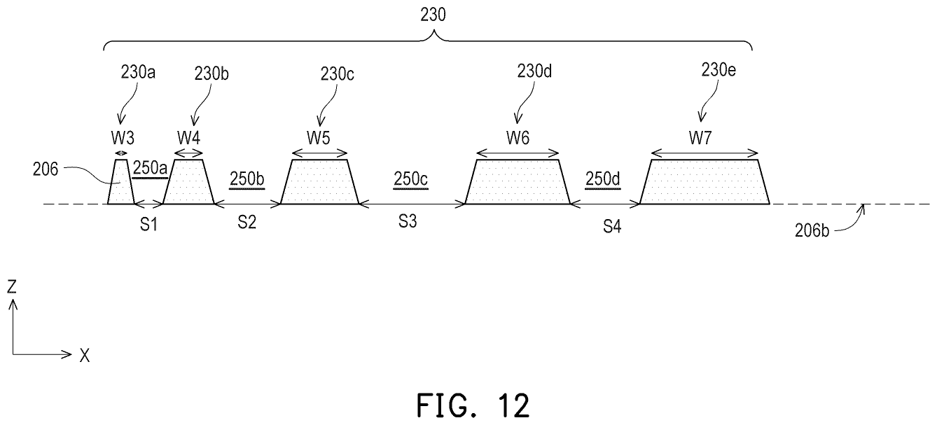

In some embodiments, referring to FIG. 12, the widths of the grating lines 230a-230e are different, and such variations are implemented according to a certain pattern. For example, the widths of the grating lines 230a-230e may gradually increase or decrease along the first lateral direction, e.g., W3<W4<W5<W6<W7 or W3>W4>W5>W6>W7. The spacings may similarly vary according to a certain pattern. For example, the spacings between the grating lines 230a-230e may gradually increase or decrease along the first lateral direction, e.g., S1<S2<S3<S4 or S1>S2>S3>S4.

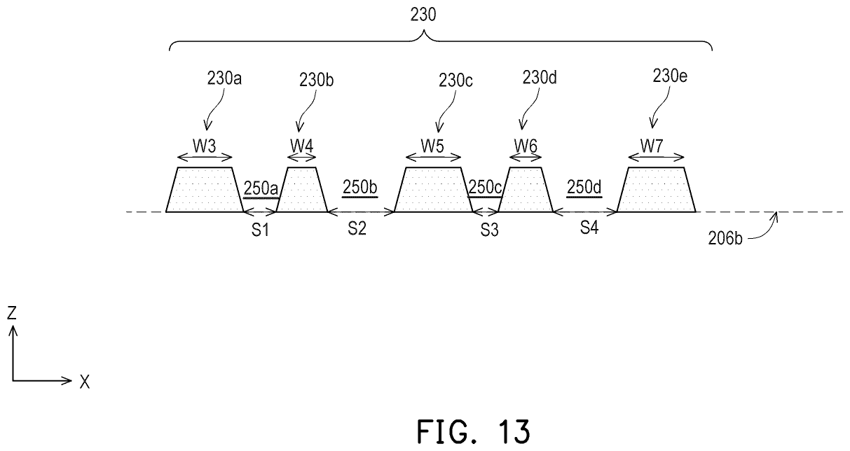

In some embodiments, referring to FIG. 13, the widths and the spacings of the grating lines 230a-230e each alternate between designated values such that the grating lines 230 are configured to have a discernable pattern along the first lateral direction. In one such example, the widths of the grating lines 230a-230e alternate between two different values, e.g., W3=W5=W7 and W4=W6. Similarly, the spacings between the grating lines 230a-230e alternate between two different values, e.g., S1=S3 and S2=S4.

In some examples, the widths W3-W7 may each be about 10 nm to about 600 nm. In some examples, a pitch Pn (e.g., P1, P2, P3, etc.) of each grating line 230, which is defined as a sum of the width Wn (e.g., W3, W4, W5, etc.) of each grating line 230 and the spacing Sn (e.g., S1, S2, S3, etc.) of each recess 250, may also vary along the first lateral direction. Referring to FIG. 11, for example, P1 is a sum of the width W3 and the spacing S1; P2 is a sum of the width W4 and the spacing S2; P3 is a sum of the width W5 and the spacing S3; and P4 is a sum of the width W6 and the spacing S4. In some examples, the pitch Pn is less than about 600 nm for an incident light having a wavelength of about 1310 nm.

In some embodiments, referring again to FIG. 11 as an example, depths of the recesses 250 may also vary along the first lateral direction, where the depths each extend along the vertical direction. For example, the recesses 250a and 250b may each have a depth D1, while the recesses 250c and 250d may each have a depth D2 that is less than the depth D1. In some embodiments, referring to FIG. 11, the depths D1 and D2 are both less than the thickness T1 of the coupler layer 206 such that the recesses 250 do not penetrate through the coupler layer 206. In some embodiments, referring to FIGS. 4-7, 12, and 13, for example, the depths of the recesses 250 is substantially the same as the thickness T1 such that the recesses 250 penetrate through the coupler layer 206. The depths D1 and D2 may be alternatively considered as heights of the grating lines 230.

The various depths of the recesses 250 may be achieved by varying parameters of an etching process used to pattern the coupler layer 206 to form the grating lines 230. For example, the various depths are achieved by changing the duration of the etching process applied to different portions of the coupler layer 206 that correspond to positions of the different recesses 250. In this regard, the recesses (e.g., the recesses 250a and 250b) with a greater depth (e.g., the depth D1) are etched for a longer duration than the recesses (e.g., the recesses 250c and 250d) with a shallower depth (e.g., the depth D2). In some examples, the depths D1 and D2 may each be about 70 nm to about 210 nm. In some examples, the depth D1 may be at least about 200 nm and the depth D2 may be at least about 100 nm. Though not depicted herein, two adjacent recesses 250 may be configured with different depths. For example, the recess 250b has the depth D1 and the recess 250c has the depth D2.

It is noted that the present disclosure does not limit the various dimensions (e.g., the depths D1 and D2, the widths Wn, the spacings Sn, the pitches Pn, etc.) of the grating lines 230 and the recesses 250 described above to any particular values, nor to any particular patterns of variation. In fact, according to some embodiments of the present disclosure, these dimensions may be intentionally randomized to reduce optical reflection (e.g., optical noise) of the incident light off the grating coupler 224, thereby improving the coupling efficiency of the grating coupler 224. For example, the widths Wn may first decrease and then increase, while the spacings Sn may continuously decrease, from the grating line 230a to the grating line 230e along the first lateral direction. While the aforementioned dimensions of the grating lines 230 are not limited to any specific values, a grating coupler, such as the grating coupler 224, configured with dimensions within the numeric ranges described herein may exhibit enhanced device performance in terms of peak loss of the photonic die 100, for example.

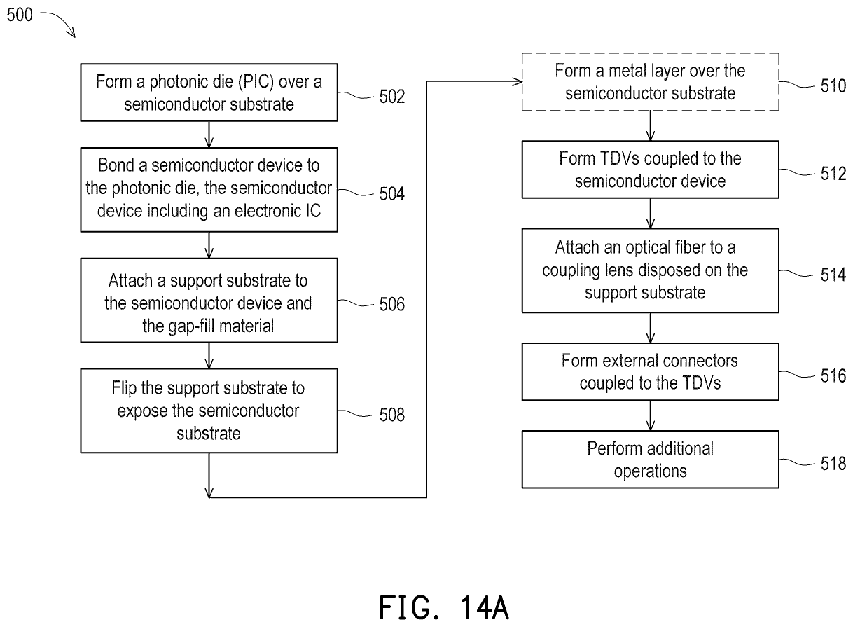

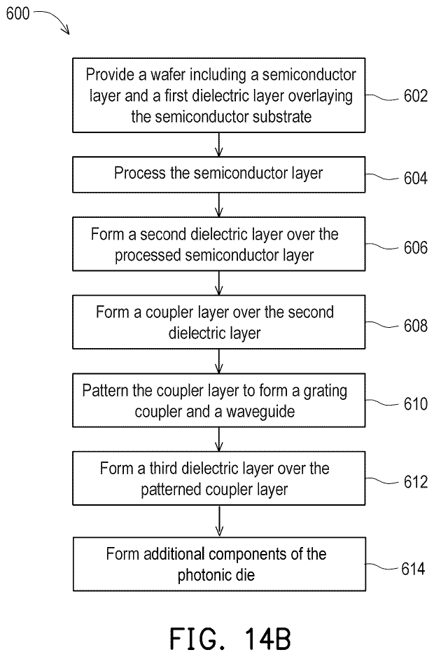

FIG. 14A illustrates a flowchart of a method 500 to form the optical package 1000 described above, according to one or more embodiments of the present disclosure. It is noted that the method 500 is merely an example and is not intended to limit the present disclosure. Accordingly, it is understood that additional operations may be provided before, during, and after the method 500 of FIG. 14A, and that some other operations may only be briefly described herein. In some embodiments, operations of the method 500 may be associated with cross-sectional views of the optical package 1000, or a portion thereof, at various fabrication stages as shown in FIGS. 15-27, which will be discussed in further detail below.

At operation 502, the photonic die 100 including the various optical components and the portion 205 disposed over the semiconductor substrate 202 is formed. The photonic die 100 may be formed via a method 600 as depicted in FIG. 14B, according to one or more embodiments of the present disclosure. It is noted that the method 600 is merely an example and is not intended to limit the present disclosure. As such, additional operations may be provided before, during, and after the method 600 of FIG. 14B. In some embodiments, operations of the method 500 may be associated with cross-sectional views of the portion 205 of the photonic die 100 at various fabrication stages as shown in FIGS. 15-20.

At operation 602, referring to FIGS. 15 and 16, a semiconductor wafer W including the semiconductor substrate 202, the dielectric layer 204 (alternatively referred to as the first dielectric layer 204) disposed on the semiconductor substrate 202, and a semiconductor layer 221 disposed on the dielectric layer 204 is provided. In the present embodiments, the semiconductor wafer W is configured to provide the photonic die 100 described in detail herein. Accordingly, a portion of the semiconductor wafer W depicted in FIG. 15 is alternatively labeled as the photonic die 100, which includes the first portion 100A adjacent to the second portion 100B. The semiconductor wafer W may be a silicon-on-insulator (SOI) wafer including a silicon substrate (e.g., the semiconductor substrate 202), a silicon oxide (SiO₂) layer (e.g., the dielectric layer 204) disposed on the silicon substrate, and a silicon layer (e.g., semiconductor layer 221) disposed on the silicon dioxide layer. The dielectric layer 204 may entirely cover a top surface or the frontside FS of the semiconductor substrate 202. The semiconductor layer 221 may entirely cover a top surface of the dielectric layer 204.

The semiconductor substrate 202, the dielectric layer 204, and the semiconductor layer 221 may each include other alternative or additional materials. For example, the semiconductor material in the semiconductor substrate 202 and the semiconductor layer 221 may each include silicon; germanium; a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; the like, or combinations thereof

In some examples, a thickness T6 of the semiconductor substrate 202 may be about 50 μm to about 760 μm, the thickness T3 of the dielectric layer 204 may be about 0 μm to about 3 μm as described above, and a thickness T7 of the semiconductor layer 221 may be about 100 nm to about 5 μm. As will be described below, the semiconductor layer 221 is processed at a subsequent operation by polishing and patterning, for example, to form the semiconductor layer 220 described in detail above with respect to FIGS. 3-5.

In some embodiments, referring to FIG. 15, the semiconductor wafer W as provided also includes at least the active components 207 formed over and/or in a portion of the semiconductor wafer W adjacent to the grating coupler 224. The photonic die 100, as described above with respect to FIG. 2, may include the active layer 201 having the optical components 207 disposed therein, the metallization layers 501 overlaying the active layer 201, and the bonding layer 505 overlaying the metallization layers 501.

For embodiments in which the semiconductor layer 220 is omitted from the photonic die 100, as depicted in FIGS. 6 and 7, the as-provided semiconductor wafer W at the operation 602 does not include the semiconductor layer 221. Alternatively, the as-provided semiconductor wafer W at the operation 602 includes the semiconductor layer 211, which is then removed completely from the semiconductor wafer W at the subsequent operation 604, leaving behind the dielectric layer 204 overlaying the semiconductor substrate 202.

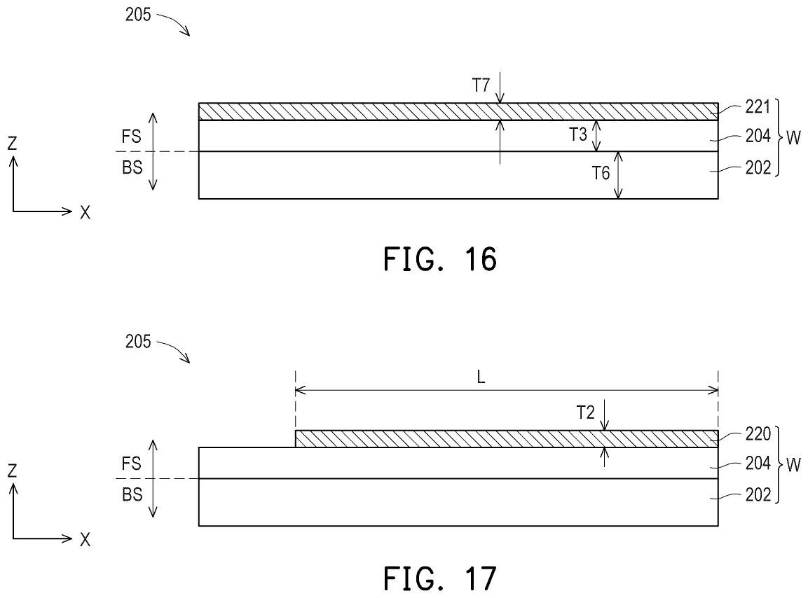

At operation 604, referring to FIG. 17, the semiconductor layer 221 is processed to form the semiconductor layer 220 as described above, where the semiconductor layer 220 only partially cover the dielectric layer 204. In some embodiments, the semiconductor layer 221 is polished or ground by any suitable method, such as a chemical-mechanical polishing/planarization (CMP) process, to reduce the thickness T7. In some embodiments, the thickness T7 is reduced to the thickness T2 for the semiconductor layer 220, where the thickness T2 may be about 10 nm to about 500 nm as described above.

Subsequently, the semiconductor layer 221 is patterned using a series of photolithography and etching processes. Generally, the patterning processes may include depositing a photoresist material (not depicted) over the semiconductor layer 221, irradiating (or exposing) the photoresist material, and developing the irradiated photoresist material to form a patterned photoresist material. The patterning processes then proceed to etching the semiconductor layer 221 using the patterned photoresist material as an etch mask, resulting in the semiconductor layer 220. The etching process may be a dry etching process, a reactive ion etching (RIE) process, a wet etching process, the like, or combinations thereof.

In the present embodiments, the semiconductor layer 220 is formed to the length L such that it overlaps the region of the grating coupler 224 containing the grating lines 230. After patterning the semiconductor layer 221, the patterned photoresist material is removed by any suitable method, such as plasma ashing or resist stripping. Furthermore, patterning the semiconductor layer 221 causes the semiconductor layer 220 to have the width W2 that gradually decreases from the edge 224e towards the edge 231e as depicted in FIG. 3. In this regard, the semiconductor layer 221 is patterned to form a substantially trapezoidal shape with the tip of the trapezoidal shape in proximity to the tapered region 226 as depicted in the top view of the photonic die 100 of FIG. 3.

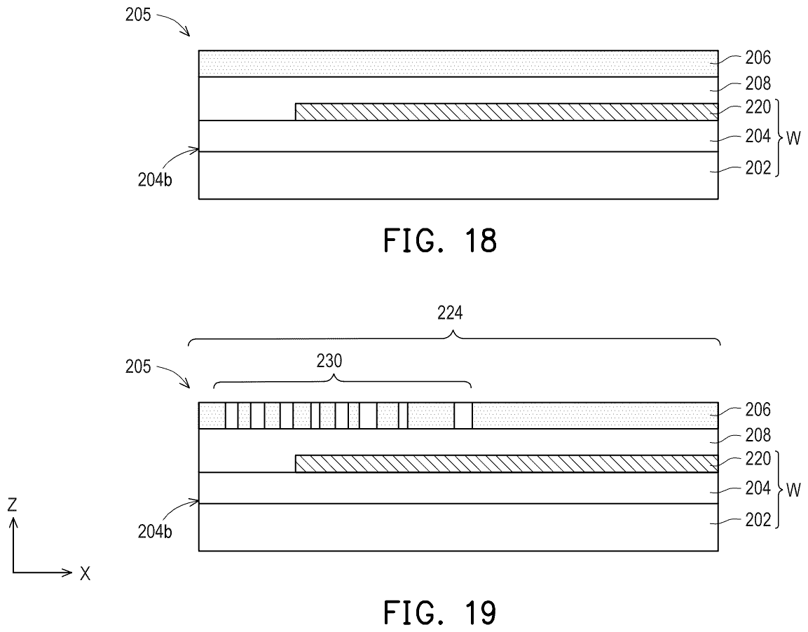

At operation 606, referring to FIG. 18, the dielectric layer 208 (alternatively referred to as the second dielectric layer 208) is formed over the semiconductor layer 220 (i.e., the processed semiconductor layer 221). The dielectric layer 208 may be deposited over the semiconductor layer 220 by any suitable method, such as chemical vapor deposition (CVD), atomic layer deposition (ALD), physical vapor deposition (PVD), spin-on coating, the like, or combinations thereof.

In some embodiments, the dielectric layer 208 and the dielectric layer 204 have substantially the same composition. For example, the dielectric layer 204 and 208 may each include silicon oxide. In some embodiments, the dielectric layer 208 directly contacts the top surface 220t and the sidewall surface 220s of the semiconductor layer 220 such that the semiconductor layer 220 is embedded in or surrounded by the dielectric layers 204 and 208.

At operation 608, still referring to FIG. 18, the coupler layer 206 is deposited over the dielectric layer 208. As described above, the coupler layer 206 includes a material having a refractive index less than that of silicon in elemental form. For example, the coupler layer 206 may include a dielectric material such as silicon nitride, lithium niobate, the like, or a combination thereof. In some embodiments, the coupler layer 206 is substantially free of silicon in elemental form. The as-deposited coupler layer 206 may entirely cover a top surface or the frontside of the dielectric layer 208. The coupler layer 206 may be deposited over the dielectric layer 208 by any suitable method, such as CVD, ALD, PVD, the like, or combinations thereof.

At operation 610, referring to FIG. 19, the coupler layer 206 is patterned to form the grating coupler 224, which includes the grating lines 230 and the tapered structure 226 (not depicted in FIG. 19), coupled to the waveguide 228 (not depicted in FIG. 19). The coupler layer 206 may be patterned using a series of photolithography and etching processes similar to those described above with respect to forming the semiconductor layer 220. For example, a photoresist material (not depicted) may be deposited over the coupler layer 206, exposed, and developed to form a patterned photoresist material. The coupler layer 206 may then be etched using the patterned photoresist material as an etch mask to form the grating lines 230 over a portion of the grating coupler 224 in the coupler layer 206. After patterning the coupler layer 206, the patterned photoresist material is removed by a suitable method. In some embodiments, the semiconductor layer 220 overlaps at least the region of the grating coupler 224 that includes the grating lines 230.

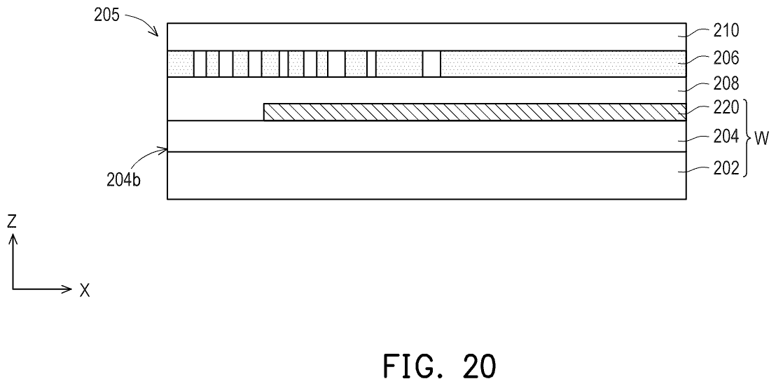

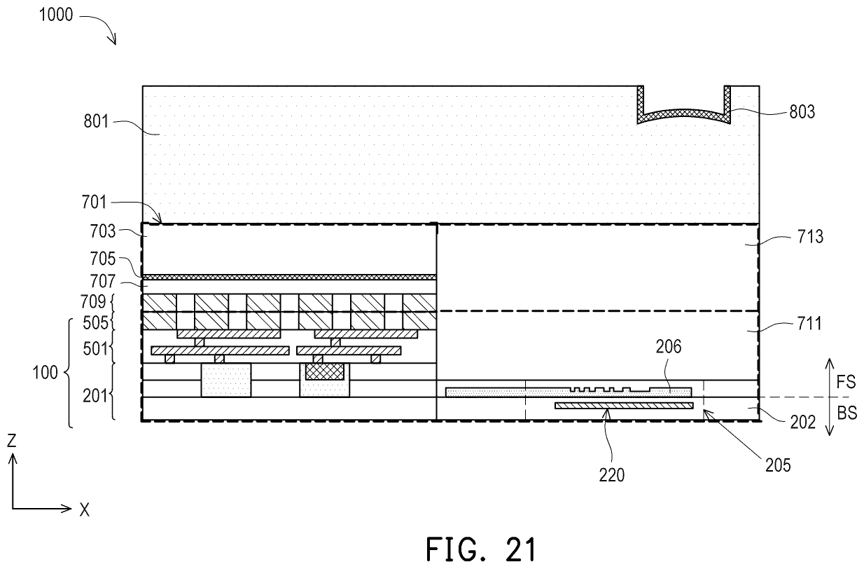

At operation 612, referring to FIG. 20, the dielectric layer 210 (alternatively referred to as the third dielectric layer 210) is formed over the patterned coupler layer 206, i.e., the grating coupler 224. The dielectric layer 210 may be deposited over the grating coupler 224 by any suitable method, such as CVD, ALD, PVD, spin-on coating, the like, or combinations thereof. In some embodiments, the dielectric layer 210 and the dielectric layer 204 have substantially the same composition. For example, the dielectric layer 204 and 210 may each include silicon oxide. In some embodiments, the dielectric layer 210 penetrates the patterned coupler layer 206 such that it fills the recesses 250 (see FIGS. 11-13) between two adjacent grating lines 230.

At operation 614, referring to FIG. 15 again, additional components of the photonic die 100 are formed over the semiconductor substrate 202. In some embodiments, the dielectric layer 210 is formed to extend laterally across both the first portion 100A and the second portion 100B such that, at operation 614, the active components 207 in the active layer 201 are formed in a portion of the dielectric layer 210 corresponding to the first portion 100A. Subsequently, the dielectric layer 711 is formed over the dielectric layer 210 across both the first portion 100A and the second portion 100B, and components including the metallization layers 501 and the bonding layer 505 are formed in a portion of the dielectric layer 711 directly above the active layer 201 in the first portion 100A, while a portion of the dielectric layer 711 directly above the coupler layer 206 remain substantially unprocessed. In this regard, the metallization layers 501 are disposed over the semiconductor substrate 202 and laterally adjacent to the coupler layer 206.

Referring to FIG. 14A and continuing with the method 500, at operation 504, the semiconductor device 701 is bonded to the photonic die 100, a frontside of the semiconductor device 701 facing the frontside FS of the semiconductor substrate 202. Referring to FIG. 21 and as described above with respect to FIG. 2, the semiconductor device 701 includes the semiconductor substrate 703 (alternatively referred to as a second semiconductor substrate 703), the device layer 705 overlaying the semiconductor substrate 703, and the interconnect structures 707 coupled to the device layer 705. The semiconductor device 701 further includes the bonding layer 709 (alternatively referred to as a second bonding layer 709) configured to be coupled to the bonding layer 505 of the photonic die 100, while the dielectric layer 713 is configured to be coupled to the dielectric layer 711 of the photonic die 100, according to some embodiments.

In some embodiments, the bonding layer 505 and the bonding layer 709 each include a plurality of hybrid bumps. Accordingly, the semiconductor device 701 may be bonded to the photonic die 100 using a dielectric-to-dielectric and metal-to-metal, or a hybrid, bonding process. Specifically, the semiconductor device 701 may be bonded to the photonic die 100 by coupling the bonding pads of the bonding layer 505 to the bonding pads of the bonding layer 709 and by coupling the dielectric layer of the bonding layer 505 to the dielectric layer of the bonding layer 709.

At operation 506, still referring to FIG. 21, the support substrate 801 is attached or bonded to the semiconductor device 701 and the dielectric layer 713 opposite to the photonic die 100. The support substrate 801 may be bonded to the semiconductor device 701 and the dielectric layer 713 using any suitable material, such as an adhesive (not depicted separately), via any suitable bonding process.

The support substrate 801 includes the coupling lens 803 disposed along a surface of the support substrate 801 opposite to a bonding interface with the semiconductor device 701. The coupling lens 803 may be formed by shaping or patterning the material of the support substrate 801 (e.g., silicon) using a series of photolithography and etching processes similar to those described above with respect to forming the semiconductor layer 220. However, any suitable process may be utilized to form the coupling lens 803.

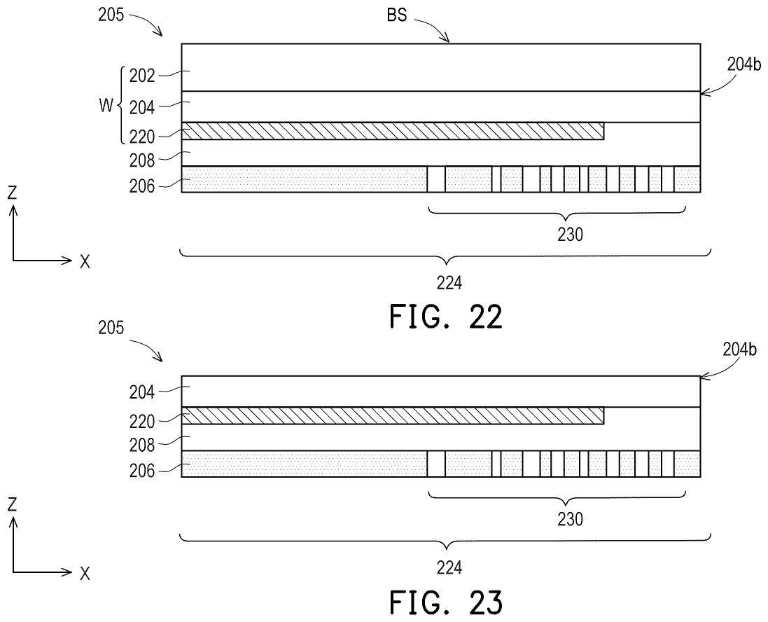

At operation 508, referring to FIG. 22, an intermediate structure of the optical package 1000 (only the portion 205 is shown in FIGS. 22-24 for emphasis) including the support substrate 801, the semiconductor device 701, and the photonic die 100 is flipped to expose the backside BS of the semiconductor substrate 202.

At operation 510, referring to FIGS. 22, 23, and 24 collectively, the metal layer 218, including the sublayers 218a and 218b, is formed over the backside BS of the semiconductor substrate 202 or embedded in a portion of the semiconductor substrate 202. In some embodiments, as depicted in FIGS. 5 and 7, the operation 510 is omitted from the method 500 such that the metal layer 218 is omitted from the photonic die 100 and the semiconductor substrate 202 remains substantially intact (i.e., the semiconductor substrate 202 is not polished or etched at the operation 510).

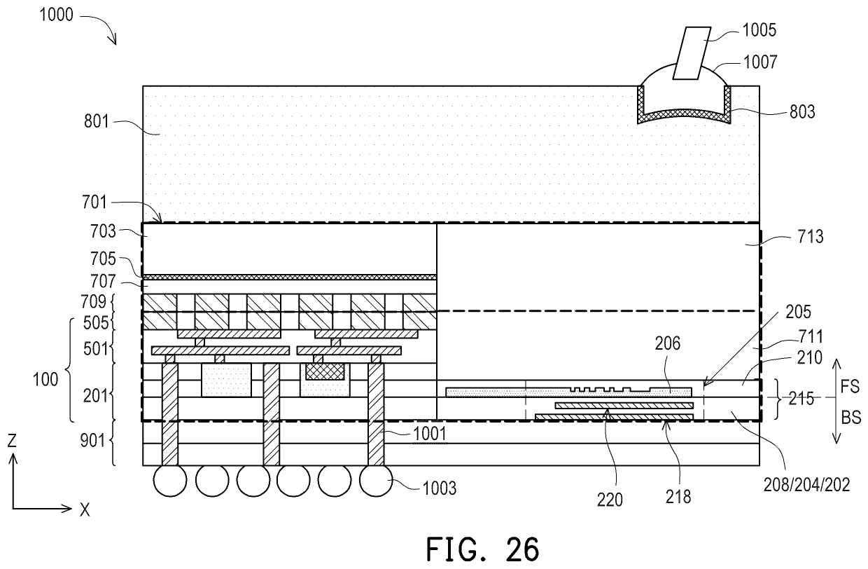

In some embodiments, referring to FIG. 23, forming the metal layer 218 includes polishing or otherwise removing a portion (e.g., within the portion 205) of the semiconductor substrate 202 to expose the bottom surface 204b of the dielectric layer 204. In some embodiments, referring to FIGS. 2 and 25, a major surface of the metal layer 218 extends along or is coextensive with the backside BS of the semiconductor substrate 202. In some embodiments, the portion of the semiconductor substrate 202 is removed from the dielectric layer 204 using a backside etching process, a grinding process, a laser lift-off process, or the like. The grinding process may include a mechanical grinding process, a CMP process, the like, or combinations thereof.

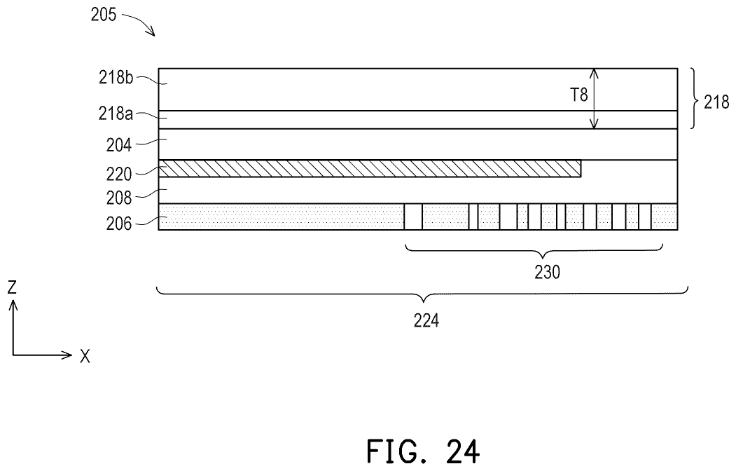

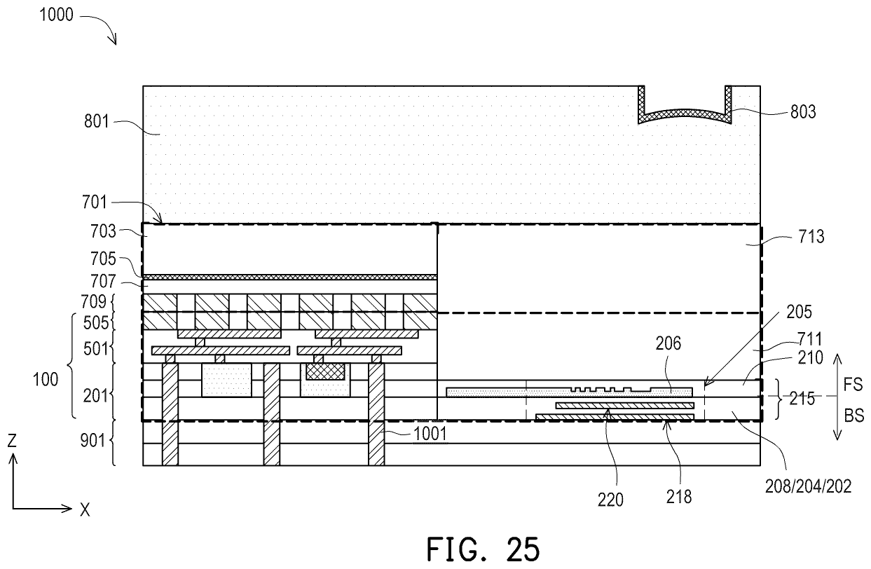

Referring to FIG. 24, the metal layer 218 is subsequently formed over the exposed bottom surface 204b of the dielectric layer 204. For embodiments in which the metal layer 218 includes multiple sublayers, such as the sublayers 218a and 218b, the sublayer 218a is deposited first and in direct contact with the exposed bottom surface 204b of the dielectric layer 204. In some embodiments, one or more sublayers of the metal layer 218 further includes a seed layer configured to accommodate the deposition process. In one such example where the sublayer 218a includes copper, a seed layer (not depicted separately) may be first deposited on the dielectric layer 204 before depositing the copper layer thereover.

The sublayers 218a and 218b, and any corresponding seed layer(s), may each be deposited by any suitable method, such as ALD, PVD, CVD, electroplating, electroless plating, the like, or combinations thereof. The as-deposited metal layer 218 may be planarized by a CMP process, for example. For embodiments in which the semiconductor substrate 202 is partially removed before forming the metal layer 218, the as-deposited metal layer 218 is planarized or polished until the backside BS of the semiconductor substrate 202 is revealed. For embodiments in which the semiconductor substrate 202 is entirely removed before forming the metal layer 218, the as-deposited metal layer 218 is planarized or polished in preparation for additional operations (e.g., formation of the dielectric layers 901). In some examples, the resulting metal layer 218 has a thickness T8 of about 10 nm to about 10 μm.

At operation 512, referring to FIG. 25, a plurality of the TDVs 1001 extending through the photonic die 100 and coupled to the semiconductor device 701 are formed. Before forming the TDVs 1001, the dielectric layers 901 are formed over the backside BS of the semiconductor substrate 202. The dielectric layers 901 may any suitable dielectric material, such as silicon oxide. In some embodiments, the dielectric layers 901 have compositions substantially the same as that of any of the dielectric layers 204, 208, and 210.

Thereafter, the TDVs 1001 may be formed by forming a plurality of TDV openings that extend through portions of the photonic die 100, such as the dielectric layers 901 and the active layer 201. The TDV openings may be formed by a series of photolithography and etching processes similar to those described above with respect to forming the semiconductor layer 220. Subsequently, a metal layer may be deposited in the TDV openings by any suitable method, such as CVD, PVD, electroplating, electroless plating, the like, or combinations thereof. The deposited metal layer may then be planarized using any suitable method, such as a CMP process. In some embodiments, the TDVs 1001 includes any suitable materials, such as copper, tungsten (W), aluminum, titanium, tantalum, titanium nitride, tantalum nitride, ruthenium, manganese, silver (Ag), gold (Au), platinum (Pt), the like, or combinations thereof.

At operation 514, referring to FIG. 26, the optical fiber 1005 is attached to the support substrate 801 at a location corresponding to the coupling lens 803. The optical fiber 1005 may be bonded or attached to the support substrate 801 using the optical glue 1007, which may include a polymeric adhesive, such as epoxy. In some embodiments, the optical glue 1007 has a refractive index of about 1 to about 3. However, any suitable material or bonding mechanism may be utilized for attaching the optical fiber 1005 to the support substrate 801 at the coupling lens 803.

At operation 516, still referring to FIG. 26, the external connectors 1003 coupled to the TDVs 1001 are formed over the backside BS of the semiconductor substrate 202. In some embodiments, the external connectors 1003 are formed to provide conductive regions for contact between the TDVs 1001, thus the semiconductor device 701, and other external devices.

The external connectors 1003 may be conductive bumps (e.g., C4 bumps, ball grid arrays, microbumps, etc.) or conductive pillars utilizing materials such as solder and copper. For embodiments in which the external connectors 1003 are contact bumps, the external connectors 1003 may include a material such as tin (Sn), or other suitable materials, such as silver, lead-free tin, copper, or combinations thereof. For embodiments in which the external connectors 1003 are tin solder bumps, the external connectors 1003 may be formed by initially forming a layer of tin using methods such as evaporation, electroplating, printing, solder transfer, ball placement, the like, or combinations thereof. Once a layer of tin has been formed, a reflow may be performed to shape the material into the desired bump shape.

At operation 518, additional operations may be performed to the optical package 1000. In some embodiments, the optical package 1000 is further integrated into a three-dimensional (3D) package 2000. For example, the 3D package 2000 may be configured as a chip-on-wafer-on-substrate (CoWoS®) package, an InFO package, a system-on-integrated-chips (SoIC) package, or the like. For illustration purposes only, the 3D package 2000 is configured as a CoWoS® package in the depicted embodiment of FIG. 27.

The 3D package 2000 may include, in addition to the optical package 1000, a second semiconductor device 1113 (alternatively referred to as a second semiconductor device 1113) separated from the optical package 1000 by an encapsulant 1119, an interposer substrate 1101 (and corresponding external connectors 1109), and a substrate 1121 (and corresponding external connectors 1123). The semiconductor device 1113 may include another EIC that is intended to work with the optical package 1000. The semiconductor device 1113 may include, for example, a memory device such as a high bandwidth memory (HBM) module, a hybrid memory cube (HMC) module, or other device that includes multiple stacked memory dies, an ASIC device, the like, or combinations thereof.

Referring to FIG. 27, forming the 3D package 2000 may include bonding the optical package 1000 and the semiconductor device 1113 to the interposer substrate 1101 by any suitable method. The interposer substrate 1101 may include a semiconductor substrate, metallization layers, and TDVs. As depicted herein, the TDVs of the interpose substrate 1101 may be coupled to external connectors 1109, which are similar to the external connectors 1003. The optical package 1000 may be attached to the interposer substrate 1101 by aligning the external connectors 1003 with conductive portions of the interposer substrate 1101. The encapsulant 1119 may subsequently be applied and planarized to fill gap regions between the optical package 1000 and the semiconductor device 1113. The encapsulant 1119 may include a molding compound, epoxy, the like, or a combination thereof, and may be applied by compression molding, transfer molding, or the like. Though not depicted, an underfill material may be deposited in the gap regions before depositing the encapsulant 1119.

Furthermore, the interposer substrate 1101 having the optical package 1000 and the semiconductor device 1113 bonded thereto may be further bonded to a substrate 1121 through the external connectors 1109. The substrate 1121 may include a package substrate, which may be a printed circuit board (PCB) or the like. The substrate 1121 may include one or more dielectric layers and electrically conductive features, such as conductive lines and vias. In some embodiments, the substrate 1121 includes through-vias, active devices, passive devices, the like, or combinations thereof. The substrate 1121 may further include conductive pads formed at the upper and lower surfaces of the substrate 1121. Additionally, the substrate 1121 may be prepared for further processing by forming external connections 1123 on an opposite side of the substrate 1121 from the optical package 1000, where the external connections 1123 may be formed using similar processes and materials as the second external connectors 1109 or 1003. By attaching the interposer substrate 1101 to the substrate 1121, the formation of the 3D package 2000, configured as a CoWoS® package, is completed.

In one aspect, the present disclosure relates to an optical structure that includes a substrate, a first dielectric layer disposed over the substrate, a coupler layer disposed over the first dielectric layer, a grating coupler formed in a first portion of the coupler layer, and a semiconductor layer disposed between the first dielectric layer and the coupler layer. The coupler layer includes a first material having a first refractive index. The semiconductor layer includes a second material having a second refractive index greater than the first refractive index.

In another aspect, the present disclosure relates to an optical package that includes a photonic die and a semiconductor device bonded the photonic die. The optical interposer includes a semiconductor substrate, a first dielectric layer disposed over a first portion of the semiconductor substrate, a coupler layer disposed over the first dielectric layer, a grating coupler formed over a first portion of the coupler layer, and a semiconductor layer disposed between the first dielectric layer and the coupler layer. The coupler layer includes a first material having a first refractive index. The semiconductor layer includes a second material having a second refractive index less than the first refractive index.

In yet another aspect, the present disclosure relates to a method that includes providing a wafer including a semiconductor layer and a first dielectric layer overlaying a semiconductor substrate. The method includes processing the semiconductor layer such that the processed semiconductor layer partially covers the first dielectric layer, where the semiconductor layer includes a first material having a first refractive index. The method includes forming a second dielectric layer over the processed semiconductor layer. The method includes forming a coupler layer over the second dielectric layer, where the coupler layer includes a second material having a second refractive index less than the first refractive index. The method includes patterning the coupler layer to form a grating coupler. The method further includes forming metalliztion layers over the semiconductor substrate, wherein the metallization layers are laterally adjacent to the coupler layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical structure, comprising:
a substrate;
a first dielectric layer disposed over the substrate;
a coupler layer disposed over the first dielectric layer, the coupler layer including a first material having a first refractive index,
a grating coupler formed in a first portion of the coupler layer; and
a semiconductor layer disposed between the first dielectric layer and the coupler layer, the semiconductor layer including a second material having a second refractive index greater than the first refractive index.

2. The optical structure of claim 1, further comprising a metal layer extending along a bottom surface of the first dielectric layer, wherein the coupler layer extends along a top surface of the first dielectric layer.

3. The optical structure of claim 2, wherein the metal layer includes a first sublayer over a second sublayer, the first sublayer including titanium and the second sublayer including copper.

4. The optical structure of claim 1, further comprising:
a second dielectric layer disposed between the semiconductor layer and the coupler layer; and
a third dielectric layer disposed over a top surface of the coupler layer.

5. The optical structure of claim 1, wherein the first material includes silicon nitride and the second material includes silicon in elemental form.

6. The optical structure of claim 1, wherein:
the grating coupler includes a plurality of grating lines, and
the semiconductor layer overlaps the plurality of grating lines along a lateral direction in a top view of the optical structure.

7. The optical structure of claim 1, wherein the semiconductor layer has a trapezoidal shape in a top view of the optical structure.

8. The optical structure of claim 1, wherein a waveguide is formed over a second portion of the coupler layer coupled to the first portion along a lateral direction.

9. An optical package, comprising:
a photonic die, including:
a semiconductor substrate,
a first dielectric layer disposed over a first portion of the semiconductor substrate,
a coupler layer disposed over the first dielectric layer, the coupler layer including a first material having a first refractive index,
a grating coupler formed over a first portion of the coupler layer, and
a semiconductor layer disposed between the first dielectric layer and the coupler layer, the semiconductor layer including a second material having a second refractive index less than the first refractive index; and
a semiconductor device bonded to the photonic die.

10. The optical package of claim 9, further comprising:
a gap-fill material disposed over the coupler layer and adjacent to the semiconductor device;
a support substrate bonded to the semiconductor device and the gap-fill material;
a coupling lens disposed on the support substrate and configured to guide incident light towards the grating coupler; and
a via extending through the photonic die to couple to the semiconductor device.

11. The optical package of claim 9, further comprising:
an interposer substrate coupled to the optical interposer through first external connectors; and
a package substrate coupled to the interposer substrate through second external connectors.

12. The optical package of claim 9, wherein the photonic die further includes a metal layer extending along a bottom surface of the first dielectric layer, wherein the coupler layer extends along a top surface of the first dielectric layer.

13. The optical package of claim 9, wherein the first material includes silicon nitride and the second material includes silicon in elemental form.

14. The optical package of claim 9, wherein the first material includes lithium niobate and the second material includes silicon in elemental form.

15. The optical package of claim 9, wherein the photonic die further includes:
a second dielectric layer disposed between the semiconductor layer and the coupler layer, and
a third dielectric layer disposed over a top surface of the coupler layer.

16. The optical package of claim 9, wherein a waveguide is formed over a second portion of the coupler layer, the second portion coupled to the first portion along a lateral direction.

17. A method, comprising:
providing a wafer including a semiconductor layer and a first dielectric layer overlaying a semiconductor substrate;
processing the semiconductor layer such that the processed semiconductor layer partially covers the first dielectric layer, the semiconductor layer including a first material having a first refractive index;
forming a second dielectric layer over the processed semiconductor layer;
forming a coupler layer over the second dielectric layer, the coupler layer including a second material having a second refractive index less than the first refractive index;
patterning the coupler layer to form a grating coupler; and
forming metallization layers over the semiconductor substrate, wherein the metallization layers are laterally adjacent to the coupler layer.

18. The method of claim 17, wherein processing the semiconductor layer includes polishing the semiconductor layer and subsequently patterning the semiconductor layer.

19. The method of claim 17, wherein the first material includes silicon in elemental form and the second material includes silicon nitride.

20. The method of claim 17, wherein:
the wafer includes:
an optically active layer disposed between the semiconductor substrate and the metallization layers, and
a bonding layer over the metallization layers, and
the method further includes:
bonding a semiconductor device including an electronic integrated circuit to the bonding layer,
attaching a support substrate to the semiconductor device, and
forming a metal layer over a backside of the first dielectric layer opposite to the coupler layer.
